(19) United States
(12) Patent Application Publication
(10) Pub. No.: US 2024/0341170 A1
(43) Pub. Date: Oct. 10, 2024

(54) METHODS FOR PASSIVATING PEROVSKITE SOLAR CELLS AND RELATED DEVICES

(71) Applicant: THE GOVERNING COUNCIL OF THE UNIVERSITY OF TORONTO, Toronto (CA)

(72) Inventors: Edward Hartley SARGENT, Toronto (CA); Hao CHEN, Toronto (CA); Sam TEALE, Toronto (CA); Bin CHEN, Toronto (CA)

(21) Appl. No.: 18/627,775

(22) Filed: Apr. 5, 2024

Related U.S. Application Data
(60) Provisional application No. 63/494,786, filed on Apr. 7, 2023.

(51) Int. Cl. H10K 85/50; H10K 30/85; H10K 30/86; H10K 71/12

(52) U.S. Cl. CPC H10K 85/50; H10K 30/85; H10K 30/86; H10K 71/12

(57) ABSTRACT

There is provided a light-harvesting heterostructure for a photovoltaic device. The photovoltaic device includes at least an electron-transport layer and a hole-transport layer. The light-harvesting heterostructure includes a 3D perovskite material contacting one of the electron-transport layer and the hole-transport layer. The light-harvesting heterostructure also includes a 2D perovskite capping material extending over at least a portion of the 3D perovskite material and contacting another one of the electron-transport layer and the hole-transport layer. The 2D perovskite capping material includes one or more perovskite layers, each perovskite layer having a corresponding width n, wherein a majority of the corresponding width n is greater or equal to 3. The 2D perovskite capping material also includes a spacer extending between two subsequent perovskite layers.

### CROSS-REFERENCE RELATED TO APPLICATION

This application claims benefit of U.S. Provisional Appln. No. 63/494,786, filed Apr. 7, 2023, the entire contents of which are hereby incorporated by reference as if fully set forth herein, under 35 U.S.C. § 119 (e).

### STATEMENT REGARDING GOVERNMENT SUPPORT

The techniques herein described are related to federally sponsored research and development under United States Department of the Navy, Office of Naval Research Grant (N00014-20-1-2572). The United States government has certain rights in this invention.

### TECHNICAL FIELD

The technical field generally relates to reduced-dimensional perovskite-based materials, as well as related devices, and methods for manufacturing such materials and devices. More particularly, the technical field relates to techniques for passivating inverted structure perovskite solar cells, including related devices and methods.

### BACKGROUND

The energy landscape of reduced-dimensional perovskites (RDPs) can be tailored by adjusting their layer width (n). Recently, 2D/3D heterostructures containing n=1 and 2 RDPs have produced PSCs with >25% power conversion efficiency (PCE). Unfortunately, this method does not translate to other types of devices.

Challenges still exist in the field of reduced-dimensional perovskites and their implementation in different devices.

### SUMMARY

In accordance with one aspect, there is provided a photovoltaic device, including:
a substrate;
a hole-transport layer coating at least a portion of the substrate;
a light-harvesting heterostructure coating at least a portion of the hole-transport layer, the light-harvesting heterostructure including:
   a 3D perovskite material; and
   a 2D perovskite capping material extending over at least a portion of the 3D perovskite material, the 2D perovskite capping material including:
      one or more perovskite layers, each perovskite layer having a corresponding width n, wherein a majority of the corresponding width n is greater or equal to 3; and
      a spacer extending between two subsequent perovskite layers;
an electron-transport layer coating at least a portion of the light-harvesting heterostructure; and
a pair of electrodes operatively connected to the substrate, the hole-transporting layer, the light-harvesting heterostructure and the electron-transport layer.

In some embodiments, the 3D perovskite material is Cs_{0.05}MA_{0.1}FA_{0.85}PbI₃.

In some embodiments, the perovskite layers each include a compound of general formula (FA)ₙ₋₁PbₙI₃ₙ₋₁.

In some embodiments, the spacer is an organic ligand selected from the group consisting of: phenethylammonium, 4-fluoro-phenethylammonium, 3-fluoro-phenethylammonium,-fluoro-phenethylammonium, butylammonium, hexylammonium, octylammonium, and 1-naphthylmethylammonium.

In some embodiments, the hole-transport layer includes NiOₓ.

In some embodiments, wherein the electron-transport layer includes C₆₀/ALD-SnO₂ or PCBM/BCP.

In accordance with one aspect, there is provided a method for manufacturing a photovoltaic device, the method including:
coating at least a portion of a substrate with a hole-transport layer;
forming a light-harvesting heterostructure on the hole-transport layer, said forming the light-harvesting heterostructure including:
   coating the hole-transport layer with a 3D perovskite material;
   treating a surface of the 3D perovskite material with a 2D perovskite solution to form a 2D perovskite capping material extending over at least a portion of the 3D perovskite material, the 2D perovskite capping material including:
      one or more perovskite layers, each perovskite layer having a corresponding width n, wherein a majority of the corresponding width n is greater or equal to 3; and
      a spacer extending between two subsequent perovskite layers; and
coating at least a portion of the light-harvesting heterostructure with an electron-transport layer.

In some embodiments, the method further includes preparing the 3D perovskite material, said preparing the 3D perovskite material including dissolving PbI₂, MAI, CsI, and FAI in DMF:DMSO solvents to obtain a 3D perovskite solution.

In some embodiments, the method further includes spin coating the 3D perovskite solution on the hole-transport layer.

In some embodiments, the method further includes preparing the 2D perovskite solution, said preparing the 2D perovskite material including dissolving 2D ligand salts with MAI in DMF:IPA solvents.

In some embodiments, the method further includes spin coating the 2D perovskite solution on the 3D perovskite material.

In accordance with one aspect, there is provided a photovoltaic device, including:
a substrate;
an electron-transport layer coating at least a portion of the substrate;
a light-harvesting heterostructure coating at least a portion of the electron-transport layer, the light-harvesting heterostructure including:
   a 3D perovskite material; and
   a 2D perovskite capping material extending over at least a portion of the 3D perovskite material, the 2D perovskite capping material including:
      one or more perovskite layers, each perovskite layer having a corresponding width n, wherein a majority of the corresponding width n is greater or equal to 3; and
      a spacer extending between two subsequent perovskite layers;
a hole-transport coating at least a portion of the light-harvesting heterostructure; and
a pair of electrodes operatively connected to the substrate, the electron-transport layer, the light-harvesting heterostructure and the hole-transporting layer.

In some embodiments, the 3D perovskite material is Cs_{0.05}MA_{0.1}FA_{0.85}PbI₃.

In some embodiments, the perovskite layers each include a compound of general formula (FA)ₙ₋₁PbₙI₃ₙ₋₁.

In some embodiments, the spacer is an organic ligand selected from the group consisting of: phenethylammonium, 4-fluoro-phenethylammonium, 3-fluoro-phenethylammonium, 2-fluoro-phenethylammonium, butylammonium, hexylammonium, octylammonium, and 1-naphthylmethylammonium.

In some embodiments, the electron-transport layer includes SnO₂.

In some embodiments, the hole-transport layer includes Spiro-OMeTAD.

In accordance with one aspect, there is provided a method for manufacturing a photovoltaic device, the method including:
coating at least a portion of a substrate with an electron-transport layer;
forming a light-harvesting heterostructure on the electron-transport layer, said forming the light-harvesting heterostructure including:
   coating the electron-transport layer with a 3D perovskite material;
   treating a surface of the 3D perovskite material with a 2D perovskite solution to form a 2D perovskite capping material extending over at least a portion of the 3D perovskite material, the 2D perovskite capping material including:
      one or more perovskite layers, each perovskite layer having a corresponding width n, wherein a majority of the corresponding width n is greater or equal to 3; and
      a spacer extending between two subsequent perovskite layers; and
coating at least a portion of the light-harvesting heterostructure with a hole-transport layer.

In some embodiments, the method further includes preparing the 3D perovskite material, said preparing the 3D perovskite material including dissolving FAPbI₃, MAPbBr₃ and MACI in a DMF:DMSO solvent to obtain a 3D perovskite solution.

In some embodiments, the method further includes spin coating the 3D perovskite solution on the electron-transport layer.

In some embodiments, the method further includes preparing the 2D perovskite solution, said preparing the 2D perovskite material including dissolving phenethyl ammonium iodide in isopropanol.

In some embodiments, the method further includes spin coating the 2D perovskite solution on the 3D perovskite material.

In accordance with one aspect, there is proved a light-harvesting heterostructure for a photovoltaic device, the photovoltaic device including at least an electron-transport layer and a hole-transport layer, the light-harvesting heterostructure including:
a 3D perovskite material contacting one of the electron-transport layer and the hole-transport layer; and
a 2D perovskite capping material extending over at least a portion of the 3D perovskite material and contacting another one of the electron-transport layer and the hole-transport layer, the 2D perovskite capping material including:
   one or more perovskite layers, each perovskite layer having a corresponding width n, wherein a majority of the corresponding width n is greater or equal to 3; and
   a spacer extending between two subsequent perovskite layers.

In some embodiments, the 3D perovskite material is Cs_{0.05}MA_{0.1}FA_{0.85}PbI₃.

In some embodiments, the perovskite layers each include a compound of general formula (FA)ₙ₋₁PbₙI₃ₙ₋₁.

In some embodiments, the spacer is an organic ligand selected from the group consisting of: phenethylammonium, 4-fluoro-phenethylammonium, 3-fluoro-phenethylammonium, 2-fluoro-phenethylammonium, butylammonium, hexylammonium, octylammonium, and 1-naphthylmethylammonium.

In accordance with one aspect, there is proved a light-harvesting heterostructure, including:
a 3D perovskite material; and
a 2D perovskite capping material extending over at least a portion of the 3D perovskite material, the 2D perovskite capping material including:
   a plurality of perovskite layers, each perovskite layer having a corresponding width n, wherein a majority of the corresponding width n is greater or equal to 3; and
   a spacer extending between two subsequent perovskite layers.

In some embodiments the light-harvesting heterostructure can be used in a photovoltaic device. The photovoltaic device includes at least an electron-transport layer and a hole-transport layer. The 3D perovskite material contacts one of the electron-transport layer and the hole-transport layer, and the 2D perovskite capping material contacts another one of the electron-transport layer and the hole-transport layer. In some embodiments, the photovoltaic device is in an inverted configuration. In some embodiments, the photovoltaic device in in a non-inverted configuration.

In accordance with one aspect, there is proved a light-harvesting heterostructure, including:
a 3D perovskite material; and
a 2D perovskite capping material extending over at least a portion of the 3D perovskite material, the 2D perovskite capping material including:
   a perovskite layer having a width n, wherein the width n is greater or equal to 3; and
   a spacer extending over at least one surface of the perovskite layer.

In some embodiments, the perovskite layer is sandwiched between two spacers. In some embodiments the light-harvesting heterostructure can be used in a photovoltaic device. The photovoltaic device includes at least an electron-transport layer and a hole-transport layer. The 3D perovskite material contacts one of the electron-transport layer and the hole-transport layer, and the 2D perovskite capping material contacts another one of the electron-transport layer and the hole-transport layer. In some embodiments, the photovoltaic device is in an inverted configuration. In some embodiments, the photovoltaic device in in a non-inverted configuration.

Other features will be better understood upon reading of embodiments thereof with reference to the appended drawings.

### BRIEF DESCRIPTION OF THE DRAWINGS

FIGS. 1a-e illustrate a quasi-2D treatment and its effect on RDP distribution: (a) Schematic of n=1, 2, 3 and 4 reduced dimensional perovskites (b) Band alignment of 3D and RDP films with increasing confinement calculated from UPS and the optical band gap of quasi 2D perovskite films. (c) The five ligands used in the study: #1, phenethylammonium, #2, 4-fluoro-phenethylammonium, #3, 3-fluoro-phenethylammonium, #4, 2-fluoro-phenethylammonium, #5, butylammonium, #6, hexylammonium, #7, octylammonium, #8, 1-naphthylmethylammonium. (d,e) Schematic of the standard 2D and quasi-2D treatments producing n≤2 RDPs and n≥2 RDPs, respectively.

FIG. 2a-i illustrate comparison of 2D and quasi-2D treatments using different 2D ligands: (a-c) TA spectra of BTA, PEA and 3F-PEA treated films using a standard 2D treatment, and (d-f) using the quasi-2D treatment. The majority absorption in each case is from the 3D perovskite (780 nm) but has been excluded for clarity. Absorption peaks are assigned in order, a comparison with single cation quasi-2D films is found in Table S4. The inset bar charts represent the relative absorption from each RDP species. (g-h) Absorption maps from in situ TA performed during spin coating. Cs_{0.05}MA_{0.1}FA_{0.85}PbI₃ 3D perovskite films were spun at 1,500 rpm and a constant 1 ps pump-probe delay was used. The quasi-2D treatments for BTA, PEA and 3F-PEA were all dropped at 7.2 s.

FIGS. 3a-b show the formation of quasi-2D perovskite capping layers from density functional theory. The PBE+TS calculated formation energy of (a) perovskite flakes ((FA)ₙ₋₁PbₙI₃ₙ₋₁, see inset). The formation energy of FAPbI₃ is shown as a dashed line. Note that the energy required to form a single layer (PbI₂) flake (n=1 RDP) is much higher than other layer widths. (b) The formation energy of different RDPs dependent on layer width n and ligand (BTA, PEA and 3F-PEA). The same calculations were performed on HA, OTA, 2F-PEA and 4F-PEA and can be found in FIG. S21.

FIGS. 4a-f illustrate the quantification of the conduction band offset of 2D and quasi-2D surface treatments: (a-c) IPES spectra of BTA, PEA and 3F-PEA treated films using 2D and quasi-2D treatments. The dotted lines represent the gaussians used to fit the data. The shaded region represents the change in conduction band edge. IPES measurements were taken using a bandpass filter, 254 nm (4.88 eV) for Control and PEA treated films, 280 nm (4.42 eV) for BTA and 3F-PEA treated films. (d) Cross section of a typical 2D/3D heterostructure in the PIN configuration. (e,f) The band alignment of the resulting cell using the 2D or quasi-2D treatment respectively. Values in (e,f) were calculated for a PEA treatment using combined UPS and IPES.

FIGS. 5a-f illustrate the Carrier extraction and performance of quasi-2D treated PSCs: (a) Transient PL from bare films treated 3F-PEA. (b) The same films with PCBM as an electron quencher. (c) Transient photocurrent measurements for devices using 3F-PEA treated films. (d) J-V curves from control, 2D and quasi-2D treated devices. Figures of merit are averages from 20 control, 2D and quasi-2D treated devices using 3F-PEA ligands. Statistics for PEA and BTA are found in FIG. S33-35. (e) Room temperature MPP tracking of an unencapsulated device under 1-sun illumination and 50% relative humidity. (f) MPP tracking of an encapsulated device held at 65° C. under 1-sun illumination and 50% relative humidity (ISOS-L3 conditions). The * indicates the point at which the MPP tracking was paused for 12 hours.

### DETAILED DESCRIPTION

In the following description, similar features in the drawings have been given similar reference numerals. In order to not unduly encumber the figures, some elements may not be indicated on some figures if they were already mentioned in preceding figures. It should also be understood herein that the elements of the drawings are not necessarily drawn to scale and that the emphasis is instead being placed upon clearly illustrating the elements and structures of the present embodiments.

The terms “a”, “an” and “one” are defined herein to mean “at least one”, that is, these terms do not exclude a plural number of items, unless stated otherwise.

Terms such as “substantially”, “generally” and “about”, that modify a value, condition or characteristic of a feature of an exemplary embodiment, should be understood to mean that the value, condition or characteristic is defined within tolerances that are acceptable for the proper operation of this exemplary embodiment for its intended application.

Unless stated otherwise, the terms “connected” and “coupled”, and derivatives and variants thereof, refer herein to any structural or functional connection or coupling, either direct or indirect, between two or more elements. For example, the connection or coupling between the elements may be mechanical, optical, electrical, logical, or any combination thereof.

In the present description, the terms “light” and “optical”, and variants and derivatives thereof, are used to refer to radiation in any appropriate region of the electromagnetic spectrum. The terms “light” and “optical” are therefore not limited to visible light, but can also include, without being limited to, the infrared region of the electromagnetic spectrum. For example, in some implementations, the present techniques can be used with electromagnetic signals having wavelengths ranging from about 250 nm to about 2500 nm. However, this range is provided for illustrative purposes only and some implementations of the present techniques may operate outside this range. Also, the skilled person will appreciate that the definition of the ultraviolet, visible and infrared ranges in terms of spectral ranges, as well as the dividing lines between them, may vary depending on the technical field or the definitions under consideration, and are not meant to limit the scope of applications of the present techniques.

The expression “device” refers to a component or an assembly associated with a functionality. For example, an “optoelectronic device” is a device that can accomplish a specific functionality involving the use or manipulation of both charge carriers and photons (e.g., lasers, light emitting diodes, photodetectors, solar cells, sensors and imagers, and others). Many other types of devices exist, such as, and without being limitative ultrafast transistors, quantum information devices, spintronics devices, energy conversion devices, sensors and imagers, and hybrid photonics-electronics devices.

In the following description, the expressions “two-dimensional material”, “2D material”, “bidimensional material”, generally refer to material that can grow and/or extend along two axes, e.g., an x-axis and a y-axis, but not a z-axis. This is by contrast to “three-dimensional material”, “3D material”, “tridimensional material”, i.e. material that can grow and/or extend along three axes, e.g., an x-axis a y-axis, and a z-axis. Two-dimensional materials may be crystalline materials including a single layer of atoms. The expressions “low-dimensional material”, “quasi two-dimensional material”, “layered perovskites” or “Ruddlesden-Popper phase” are herein used to describe materials and/or crystals having a generally periodic structure in two dimensions (e.g., along an x-axis and a y-axis) and an atomic-size thickness that can include more than one layer of atoms in a third dimension (e.g., a z-axis). Of note, there are typically more than one atom between spacers in a 2D perovskite. There is one unit cell of the perovskite in a “fully 2D” perovskite, and then multiple unit cells in a “quasi-2D” perovskite. The term “2D perovskites” is often used to refer to any confined perovskite It will be noted that the dimensionality of the perovskite materials that will be herein described may be also defined by the periodicity of the perovskite materials along its thickness. For example, a plurality of quantum wells may be stacked one onto another with a spacing layer being provided between each pair of quantum wells. This configuration would provide the perovskite material with periodicity along the Z direction but could be referred as a two-dimensional perovskite materials because the charge carriers would be confined in each quantum well due to the presence of the spacing layer between each pair of quantum wells. In the current disclosure, the expressions “monolayer”, “single layer”, variants and combinations thereof may refer to low-dimensional perovskite materials that may have a thickness of several atoms. It will be noted that the monolayers or the single layers (periodically extending in the X and Y directions) may be stacked on top of each other, thereby producing structures having a thickness greater than the thickness of only one layer.

In the context of the present description, the term “perovskite” will be used to refer to any materials which contains a network of corner sharing BX6 octahedra that form into a ABX₃ crystal structure, wherein A and B are cations jointly bound to X, “X” being an anion. This term may be further extended to other compounds with the crystal structure A′₂Aₙ₋₁MₙX₃ₙ₊₁, wherein “A” is a smaller cation (such as, for example and without being limitative, CH₃NH₃⁺ [MA⁺] and Cs⁺), “M” a divalent metal cation (such as, for example and without being limitative, Pb²⁺ and Sn²⁺), “X” a halide (such as, for example and without being limitative, Cl⁻, Br⁻ or I⁻) and “A′” a secondary cation (usually larger than the first such as, for example and without being limitative C₄H₁₂N⁺[BA⁺] and C₈H₁₂N⁺[PEA⁺]). The expression “perovskite material” could encompass a broad variety of materials, for example and without being limitative, Cs_{0.87}MA_{0.13}PbBr₃, BABr:MAPbBr₃, MAPbBr₃, CsPbBr₃, MAPbBr₃, CsSnBr₃, CsGeBr₃, CsPb_{0.5}Sn_{0.5}Br₃, Cs₁₀MA_{0.17}FA_{0.83}Pb(BrₓI₁₋ₓ)₃, PEA₂MA₄Pb₅Br₁₆, FAPbBr₃, CsPbBr₃, CsPbBr₃, FA₍₁₋ₓ₎CsₓPbBr₃, MAPbBr₃, PEA₂Cs₃Pb₄Br₁₃, PEA₂Cs_{2.4}MA_{0.6}Pb₄Br₁₃, PEA₂Cs_{1.5}MA_{1.5}Pb₄Br₁₃, PEA₂Cs_{0.6}MA_{2.4}Pb₄Br₁₃ and PEA₂MA₃Pb₄Br₁₃.

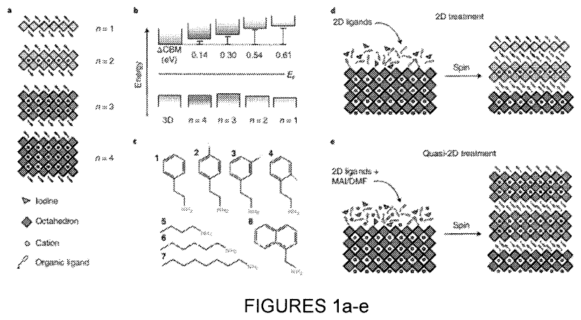

Reduced dimensional perovskites (RDPs) are perovskite quantum well (QW) layers confined between large spacers such as, for example and without being limitative, organic or inorganic ligands. The number of stacked Pb-octahedra between organic spacers determines the width of the RDP layer, e.g., n=1, 2, 3 (see FIG. 1a). Changing the RDP layer width within bulk RDP films alters the energy landscape of the resulting material, hence narrow RDP films (n s 5) produce excellent light-emitting diodes and luminescent solar concentrators.^{1,2} Although films containing wider RDPs (n≥10) have been used to produce highly stable perovskite solar cells (PSCs), these devices suffer from inferior performance due to poor carrier mobility.^{3,4} More recently, record-performing PSCs have used a 2D/3D heterostructure, fabricated by spin coating RDP (or 2D) ligands onto the surface of 3D perovskite⁵⁻¹². A comparison of PSC efficiency/stability from recent reports is found and demonstrates some of the most efficient devices reported have used this structure. Studies have revealed that this heterostructure consists of a thin layer of n=1 and/or n=2 RDPs atop bulk 3D perovskite,¹³⁻¹⁶ which increases performance via passivation and increased electron blocking.^{17,18} Electron blocking is beneficial for devices built in the negative-intrinsic-positive (NIP) architecture, in which the 2D-treated perovskite surface is coated with a hole transport layer (HTL), but, when used in the generally more stable¹⁹⁻²² inverted (PIN) structure, this strategy has achieved mixed results. Chen et al. found that a 2D treatment applied to inverted cells improved the open circuit voltage (V_{OC}) but reduced fill factor (FF),²³ and Bai et al. found that introducing a small amount of a 2D ligand into the antisolvent improved device performance, opening the door for further study of the width of RDPs and indeed their presence.²⁴ On the other hand, Park et al., Zhou et al., and La-Placa et al. all found that using a 2D layer in a PIN device reduced PCE due to lower current and fill factor.²⁵⁻²⁷ The experiments and corresponding results that will be herein described support that reducing confinement in the 2D layer could reduce electron blocking and produce inverted PSCs with relatively good performance.

The present techniques broadly relate to a quasi-2D surface treatment of a 3D perovskite material. More specifically, the present techniques allow altering the QW widths in a 2D/3D perovskite heterostructure. These techniques can be useful, for example, to improve at least one characteristic of inverted PSCs by reducing the confinement within the 2D capping layer to reduce the electron barrier between the 3D and 2D perovskite species. In some embodiments, the techniques allow producing highly stable NiOₓ-based PSCs with certified efficiency values. The present techniques could be extended to other metal halide-based optoelectronics devices in which well-passivated, negative-intrinsic contacts may be desirable or advantageous. Examples include, but are not limited to field effect transistors, light emitting diodes, photodetectors, gamma detectors, neutron detectors and memristors.

In accordance with one aspect, there is provided a light-harvesting heterostructure for a photovoltaic device. The photovoltaic device includes at least an electron-transport layer and a hole-transport layer. The light-harvesting heterostructure includes a 3D perovskite material contacting one of the electron-transport layer and the hole-transport layer. The light-harvesting heterostructure also includes a 2D perovskite capping material extending over at least a portion of the 3D perovskite material. The 2D perovskite capping material contacts another one of the electron-transport layer and the hole-transport layer. The 2D perovskite capping material includes one or more (i.e., at least one) layers of confined perovskite, each perovskite layer having a corresponding width n, wherein a majority of the corresponding width n is greater or equal to 3, and a spacer extending between two subsequent perovskite layers. The light-harvesting heterostructure can be used in many devices, such as, for example and without being limitative, inverted solar cells and non-inverted solar cells. In some embodiments, the 3D perovskite material is Cs_{0.05}MA_{0.1}FA_{0.85}PbI₃. In some embodiments, the 3D perovskite material may have a general formular of (CsFAMA)PbSn(I,Br,Cl)₃ In some embodiments, the perovskite layers each include a compound of general formula (FA)ₙ₋₁PbnI₃ₙ₋₁. Of note, the A-site could be FA, MA or Cs. In some embodiments, the spacer is an organic ligand. In some embodiments, the spacer is an inorganic ligand. In some embodiments, the organic ligand is selected from the group consisting of: phenethylammonium, 4-fluoro-phenethylammonium, 3-fluoro-phenethylammonium, 2-fluoro-phenethylammonium, butylammonium, hexylammonium, octylammonium, and 1-naphthylmethylammonium.

In accordance with another aspect, there is provided a photovoltaic device in an inverted configuration. The photovoltaic device in this configuration includes a substrate, a hole-transport layer coating at least a portion of the substrate, the light-harvesting heterostructure having been previously described, the light-harvesting heterostructure coating at least a portion of the hole-transport layer, an electron-transport layer coating at least a portion of the light-harvesting heterostructure, and a pair of electrodes operatively connected to the substrate, the hole-transporting layer, the light-harvesting heterostructure and the electron-transport layer. In some embodiments, the 3D perovskite material is Cs_{0.05}MA_{0.1}FA_{0.85}PbI₃. In some embodiments, the perovskite layers each comprise a compound of general formula (FA)ₙ₋₁PbnI₃ₙ₋₁. In some embodiments, the spacer is an organic ligand. In some embodiments, the spacer is an inorganic ligand. In some embodiments, the organic ligand is selected from the group consisting of: phenethylammonium, 4-fluoro-phenethylammonium, 3-fluoro-phenethylammonium, 2-fluoro-phenethylammonium, butylammonium, hexylammonium, octylammonium, and 1-naphthylmethylammonium. In some embodiments the hole-transport layer comprises NiOₓ. In some embodiments, the electron-transport layer comprises Co/ALD-SnO₂ or PCBM/BCP. In some embodiments, the electron-transport layer may comprise TiO₂ or ZnO. In some embodiments, the hole-transport layer may comprise self-assembled monolayers such as 2PACz or Me-4PACz, Spiro-OMeTAD, CuSCN or PEDOT-PSS.

There is also provided a method for manufacturing such devices. The method includes coating at least a portion of a substrate with a hole-transport layer; forming a light-harvesting heterostructure on the hole-transport layer, said forming the light-harvesting heterostructure comprising coating the hole-transport layer with a 3D perovskite material and treating a surface of the 3D perovskite material with a 2D perovskite solution to form a 2D perovskite capping material extending over at least a portion of the 3D perovskite material, the 2D perovskite capping material being similar to the one previously described; and coating at least a portion of the light-harvesting heterostructure with an electron-transport layer. In some embodiments, the method further includes preparing the 3D perovskite material, said preparing the 3D perovskite material comprising dissolving PbI₂, MAI, CsI, and FAI in DMF:DMSO solvents to obtain a 3D perovskite solution. In some embodiments, PbBr₂, PbCl₂, CsBr, CsCl, MABr, MACl, FABr, FACl, DMACl, DMAI or DMABr can be used. In some embodiments, the 3D perovskite material can be obtained via evaporation from precursor salts. In some embodiments, the method further includes spin coating the 3D perovskite solution on the hole-transport layer. In some embodiments, the method further includes preparing the 2D perovskite solution, said preparing the 2D perovskite material comprising dissolving 2D ligand salts with MAI in a DMF:IPA solvent. In some embodiments, the method further includes spin coating the 2D perovskite solution on the 3D perovskite material. In some embodiments, the 2D perovskite material can be obtained via evaporation onto the 3D perovskite material.

In accordance with another aspect, there is provided a photovoltaic device in a non-inverted configuration. The photovoltaic device in this configuration includes a substrate, an electron-transport layer coating at least a portion of the substrate, the light-harvesting heterostructure having been previously described, the light-harvesting heterostructure coating at least a portion of the electron-transport layer, a hole-transport layer coating at least a portion of the light-harvesting heterostructure, and a pair of electrodes operatively connected to the substrate, the electron-transport layer, the light-harvesting heterostructure and the hole-transporting layer. In some embodiments, the 3D perovskite material is Cs_{0.05}MA_{0.1}FA_{0.85}PbI₃. In some embodiments, the perovskite layers each comprise a compound of general formula (FA)ₙ₋₁PbnI₃ₙ₋₁. In some embodiments, the spacer is an organic ligand. In some embodiments, the spacer is an inorganic ligand. In some embodiments, the organic ligand is selected from the group consisting of: phenethylammonium, 4-fluoro-phenethylammonium, 3-fluoro-phenethylammonium, 2-fluoro-phenethylammonium, butylammonium, hexylammonium, octylammonium, and 1-naphthylmethylammonium. In some embodiments, the electron-transport layer comprises SnO₂. In some embodiments, the hole-transport layer comprises Spiro-OMeTAD.

There is also provided a method for manufacturing such devices. The method includes coating at least a portion of a substrate with an electron-transport layer; forming a light-harvesting heterostructure on the electron-transport layer, said forming the light-harvesting heterostructure comprising: coating the electron-transport layer with a 3D perovskite material and treating a surface of the 3D perovskite material with a 2D perovskite solution to form a 2D perovskite capping material extending over at least a portion of the 3D perovskite material, the 2D perovskite capping material being similar to the one having been previously described; and coating at least a portion of the light-harvesting heterostructure with a hole-transport layer. In some embodiments, the method further includes preparing the 3D perovskite material, said preparing the 3D perovskite material comprising dissolving FAPbI₃, MAPbBr₃ and MACl in DMF:DMSO solvents to obtain a 3D perovskite solution. In some embodiments, the method further includes spin coating the 3D perovskite solution on the electron-transport layer. In some embodiments, the method further includes preparing the 2D perovskite solution, said preparing the 2D perovskite material comprising dissolving phenethyl ammonium iodide in isopropanol. In some embodiments, the method further includes spin coating the 2D perovskite solution on the 3D perovskite material.

Ultraviolet photoelectron spectroscopy (UPS) and absorption spectroscopy were used to estimate the band alignment of RDP films of different QW widths (n=1 to 4) (FIG. 1b) and compare them to bulk 3D perovskite (e.g., Cs_{0.05}MA_{0.1}FA_{0.85}PbI₃). Consistent with earlier reports, little dependence between valence band maximum (VBM) and n (RDP width) was observed.^{18,28,29} Instead, quantum confinement upshifts the conduction band minimum (CBM), which induces electron blocking in devices. This detrimental effect was experimentally confirmed by comparing NIP and PIN PSCs treated with standard 2D treatments. Simulations in SCAPS-1 D³⁰ suggested that due to their deeper CBM, a capping layer of n≥3 RDPs would be beneficial to PIN solar cell performance via surface passivation with reduced resistance to carrier transport.

In bulk RDP films or layers, the average layer thickness or width n is modulated by changing the ratio of 2D ligands to 3D perovskite precursors in solution.^{1,4} Several options were explored to reproduce this for a 2D post-treatment. Distinctive results were achieved when a small amount DMF (1:200 by vol. to IPA) and MAI (1:2 by wt.) was introduced to the 2D ligands in solution, because MAI is needed to reduce the ratio of 2D ligand to A-site cation and DMF introduces Pb directly from the 3D perovskite surface. Using this strategy, 2D perovskite capping layers containing n≥3 RDP layers (FIG. 1e) were produced. In the context of the current disclosure, the 2D ligand treatment will be referred to as a quasi-2D treatment.

Zhou et al. demonstrated that adding MAI and DMF to a PEAI surface treatment improves the performance of PIN solar cells.³¹ This prior study is limited in scope however, discussing only the effect of DMF on the penetration depth of the 2D treatment. Using ToF-SIMs, the penetration depth of PEA from solutions using different DMF concentrations were prepared, and no correlation within was observed for the sample size (1:200-1:50 DMF:IPA by vol.). The origin for improved performance is attributed to the production of wider RDPs at the interface between 3D perovskite and ETL. This observation leads to the quasi-2D treatment described herein and different parameters of the quasi-2D treatment have been optimized, as it will be described in greater detail below.

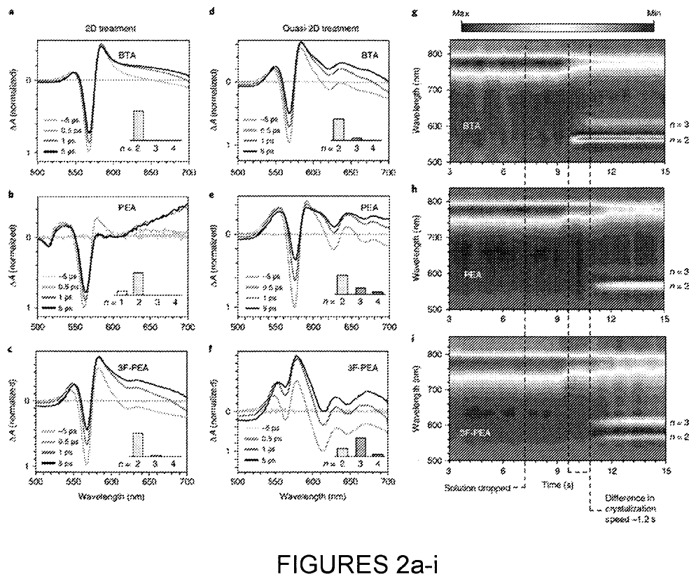

A strong dependence between QW width and bandgap exists in 2D perovskites.^{32,33} Hence, ultrafast transient absorption spectroscopy (TA) can be used to accurately identify the distribution of different 2D species in perovskite films.³⁴⁻³⁶ TA spectra of 2D and quasi-2D treated films were obtained, using the most common 2D perovskite ligands: butylammonium (BTA) and phenethylammonium (PEA) (FIGS. 2a,d and 2b,e respectively). Though the majority absorption from each film is from 3D perovskite (780 nm), each film displays bleach peaks in the 500-700 nm range, characteristic of RDPs. Similar to spectra acquired from Niu et al., the standard 2D treated films display bleach signals from n=1 and/or 2 RDPs.³⁶ Quasi-2D treated films, however, contain n≥3 RDPs, with the PEA treatment producing more n≥3 RDPs than BTA. Grazing incidence wide-angle x-ray scattering (GIWAXS) confirmed that these 2D layers lie horizontal to the substrate, as in other reports.^{5,13,15} Recently, it was documented that bulk quasi-2D perovskite films made using fluorinated PEA ligands form different QW structures compared to standard PEA.³⁵ To this end PEA-based ligands with a fluorine at each node (FIG. 1c) were tested and it was found that this has a relatively important effect on the QW distribution. Using the quasi-2D surface treatment approach, 3-fluoro-phenethylammonium (3F-PEA) produces a 2D/3D heterojunction containing a majority n=3 RDP (FIG. 2f). Depictions of all 2D ligands mentioned are found in FIG. 1c.

To better understand why different ligands produce different RDP distributions, TA was measured in situ while spin coating quasi-2D treatments (FIG. 2g-i). With a 1 ps pump-probe delay and a 0.3 s time resolution, the films were spun at 1,500 rpm and the 2D treatment was dynamically deposited. A reduction in 3D perovskite absorption is apparent ˜2.4 s after solution deposition for all samples. For the BTA treatment, this reduction in 3D bleach is concurrent with the arrival of a strong n=2 bleach. For the PEA-based treatments, the 2D signal does not appear until ˜1.2 s after the 3D bleach reduction. It has been suggested that bulkier organics intercalate more slowly which induces them to form wider RDPs. [34] These results agree with this suggestion, indicating that π-π stacking ligands form wider RDPs due to slower crystallization which suppresses narrower RDP formation. This is corroborated by films treated with hexyl ammonium (HA) and octyl ammonium (OTA) ligands, which demonstrate an increased presence of n≥3 RDP with increasing ligand length. To investigate the effect of increased π-π stacking, samples with 1-naphthylmethylammonium were treated (FIG. 1c) but it has been found that the quasi-2D treatment significantly reduced the RDP absorption in the TA spectra. Different experiments were conducted to determined why 3F-PEA forms wider RDPs. Standard PEA produces n=2 and 3 simultaneously, whereas 3F-PEA forms n=3 one frame (0.3 s) before the appearance of n=2, suggesting that n=3 is preferentially formed out of the precursor complex.

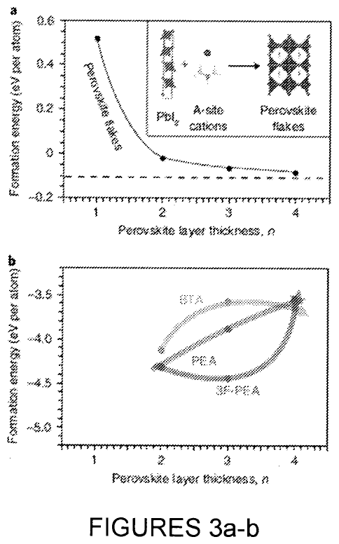

DFT calculations to compute the formation energy of n=1, 2, 3 and 4 RDPs for each ligand have been carried out. As previously reported,⁴ the formation energy of n=1 RDP was found to be the lowest for all ligands, however, this was not supported by experimental findings or results from other studies.^{36,37} Nonetheless, considering that forming single layers of PbI₂ is considerably more energy intensive than larger slabs (FIG. 3a) it seems reasonable that n=1 layers are less likely to form, especially when excess cations are available as within the quasi-2D treatment. Hence, the formation energy of n≥2 RDPs was compared.

It has been found that the formation energy increases with increasing width, however, bonding different ligands onto 2D perovskite flakes (FAₙ₋₁PbnI₃ₙ₋₁) introduces different types of strain into the system which is released through different distortions of the perovskite. The specific orientation and arrangement of the ligands caused by the fluorine atom in 3F-PEA (structure taken from³⁵) introduces larger strain compared to PEA or BTA, manifesting as larger distortions, and therefore larger perovskite flakes are needed to fully release the additional strain. As a result, a sweet spot for n=3 is found in the formation energy of 3F-PEA (FIG. 3b), which results in the preferential formation of n=3 revealed in the TA data. The formation energies for each of the ligands 1-7 in FIG. 1c were calculated, but only 3F-PEA possessed a preference for n≥3.

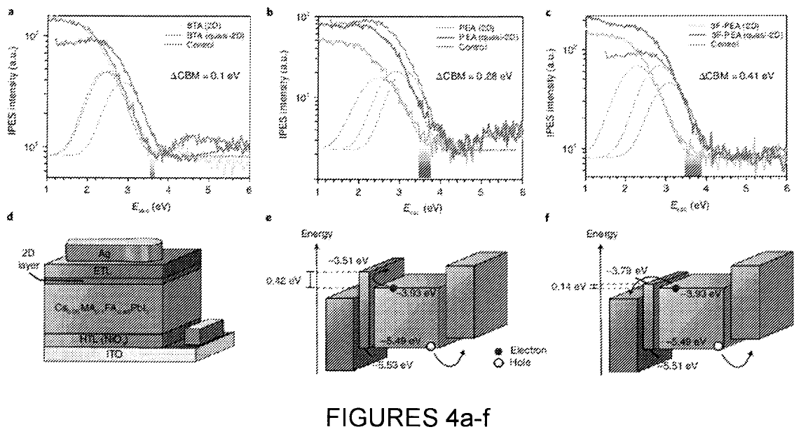

The present techniques allow modulating the n-distribution of 2D/3D heterojunctions with the aim of reducing the electron barrier at the perovskite ETL interface. To verify this, surface sensitive IPES (inverse photoelectron spectroscopy), which directly measures the conduction band of the first few nm^{29,38-41} of film, was used. Following work from Endres et al.⁴² Gaussian fittings were used to extract the CBM and it has been found that, as expected, the CBM of 2D treated surfaces are upshifted compared to controls (FIG. 4a-c). Using the quasi-2D treatment, the 2D/3D CBM offset is reduced significantly for PEA and 3F-PEA treated films relative to their n=1 (and/or 2) analogues (0.42 to 0.14 eV and 0.49 to 0.08 eV respectively), but less so for BTA (0.41 to 0.31 eV). The potential of the film surfaces using Kelvin probe force microscopy (KPFM) was measured and a similar trend was observed. This complements the results in the previous section which suggest that the quasi-2D treatment using BTA produces fewer n≥3 RDP than PEA or 3F-PEA. Surface sensitive UPS was also perform on controls, 2D and quasi-2D treated films to produce the schematics in FIG. 4e,f. Similar to the plot in FIG. 1b and several previous reports,^{18,28,29} altering the RDP width has little effect on the VBM, reducing confinement simply shifts the conduction band deeper, closer to 3D perovskite.

To explore device implications, charge transport in BTA, PEA and 3F-PEA treated films using the 2D and quasi-2D treatments was investigated. Photoluminescence quantum yield (PLQY) increases after the standard 2D treatment for each ligand, suggesting a reduced density of non-radiative recombination centers.⁸ This effect is enhanced slightly by the quasi-2D treatment indicating improved passivation. A similar trend is visible in transient photoluminescence (TRPL) results, where longer lifetimes are recorded for 2D and quasi-2D treated films (a summary of lifetimes is found in Table S3). The modestly improved passivation of the quasi-2D treatment may be due to the addition of MAI, which has also been reported to passivate perovskite surfaces.⁴³

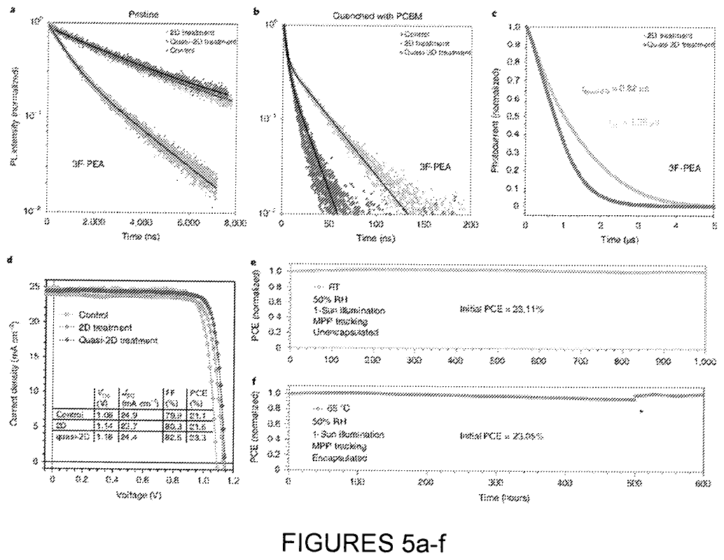

Following the work of Kirchatz et al., PCBM was deposited atop the perovskite as an ETL and used the quenched T₁ lifetimes to compare charge extraction (FIG. 5b).⁴⁴ The quenched T₁ lifetime of the control film was 4.6 ns. After deposition of 3F-PEAI this doubled to 9.2 ns, suggesting that the standard 2D treatment impedes the flow of electrons from perovskite to ETL. Using the quasi-2D treatment this was reduced to 4.9 ns implying considerably improved extraction compared to the standard 2D treatment. A similar trend is seen using BTA and PEA (FIG. S24). For quantitative values these measurements were repeated using power dependent TA and space charge limited current (SCLC) measurements. From TA, it has been found that both 2D and quasi-2D treatments reduced surface recombination velocity significantly (˜600 cm s⁻¹ to ˜300 cm s⁻¹). SCLC measurements show a similar trend but the overall effect is less significant as the entire film is examined, not simply the interfaces.

In PSCs using bulk RDPs films, which contain mixed dimensional phases, have reduced mobility due to charge trapping in higher n species.³ To understand why this is not necessarily the case in 2D/3D heterostructure films, TA was used to measure charge dynamics. Using a 450 nm pump at a low power (5 μJ/cm²) to avoid Auger recombination,⁴⁵ the 2D and 3D layers of 2D and quasi-2D treated films were excited. Measuring the n=2 bleach decay (˜570 nm) using monoexponential fits, the carrier funneling rates for both treatments were calculated. For a standard 2D treated film, there are no n>2 peaks present (FIG. 2a), thus charges are expected to funnel directly from n=2 to 3D perovskite,^{1,46} for which a 28.6 ps decay time was observed. When a favorable pathway for electrons is generated by adding a layer of PCBM, a faster decay (7.5 ps) has been observed. Repeating these measurements with a quasi-2D treated film, a decay without PCBM of 5.8 ps was observed, suggesting that charges are funneling to the now present n>2 species.^{1,46} However, adding a layer of PCBM resulted in an even faster decay (1.2 ps) indicating that charge trapping does not play a limiting role in charge extraction.

To gauge the effect of the 2D and quasi-2D treatments in full device stacks, transient photovoltage and photocurrent measurements (FIG. 5c) were conducted. Following an existing method⁴⁷, devices were biased with the same white light intensity to reach near-V_{OC} conditions and photoexcited with low power laser pulses to generate small photovoltage perturbations (ΔV kept to lower than 20 meV). Monoexponential fits were used to estimate the carrier lifetime at V_{OC} and J_{SC} conditions. A slower decay in photovoltage for the quasi-2D treated films compared to the standard 2D was observed, which is consistent with the TRPL results and indicates a reduction in trap states in the absorber. More importantly, a faster decay in photocurrent for the quasi-2D treated films (T=0.82 μs compared to T=1.28 μs for 3F-PEA treated films) was observed, which suggests a significant improvement in carrier extraction.⁴⁸ Additionally conductive atomic force microscopy (c-AFM) was performed on these films, revealing increased conductivity in quasi-2D treated films.

Devices with an ITO/NiOₓ/perovskite/PCBM/BCP/Ag structure were prepared, using different surface treatments (BTA, PEA, 2F-PEA, 4F-PEA and 3F-PEA; standard 2D and quasi-2D) for statistical analysis (S33-36). In agreement with the findings herein described, increased n≥3 RDPs results in more efficient charge extraction, 3F-PEA outperformed PEA and BTA treated devices. Improved performance of quasi-2D over the standard 2D treated devices derives mainly from FF and J_{SC} improvements; a typical set of J-V curves are shown in FIG. 5d along with figures of merit. To check for reproducibility, statistics for devices fabricated over a 1-year period. To confirm that improved passivation alone was not the cause of increased FF, the effect of reducing only the surface trap density in SCAPS-1 D was simulated, and it has been found that a 20 mV difference in V_{OC} would correspond to a ˜0.5% increase in FF, rather than the 2.2% increase manifested.

A quasi-2D treated device was certified at the National Renewable Energy Laboratory (NREL). The C₆₀/BCP based device produced a record quasi-steady state certified PCE for inverted PSCs of 23.91% (with FF=83.46, J_{SC}=24.90 mAcm⁻² and V_{OC}=1.15 V). A voltage loss of 0.38 V is the lowest documented for a NiOₓ based perovskite solar cell.⁴⁹

In light of the above, the performance of NiOₓ-HTL, inverted PSCs has been optimized, because this architecture has shown a relatively high stability at elevated temperatures.^{19,49,50} However, 2D treatments have been shown to be unstable above 50° C., degrading in a matter of hours.⁵¹ It was crucial to ascertain whether any new 2D treatment could withstand high temperatures. 2D and quasi-2D treated films were prepared and subsequently heated at 65° C. for 20 hours, while periodically measuring their characteristics with TA. The n distribution of both treatments was robust under heating, suggesting that the quasi-2D treatment could be used to produce relatively stable devices.

The stability of the devices has been assessed under accelerated-aging conditions according to International Summit on Organic Photovoltaic Stability (ISOS) protocols.⁵² The maximum power point of two quasi-2D treated devices under illumination at ˜50% relative humidity was tracked. An unencapsulated device was monitored at room temperature (RT) for 1000 hrs (ISOS-L-11), and an encapsulated device on a temperature controllable stage was monitored at 65° C. for 500 hrs (ISOS-L-3), the results are shown in FIG. 5e,f. The unencapsulated RT devices showed no degradation after 1000 hrs of MPP tracking (4.9% increase in PCE), whereas the device baked at 65° C. lost ˜8% of its maximum PCE after 500 hrs. Based on a linear extrapolation from this data, the T₈₀ lifetime of this device is estimated to be ˜1190 hrs.^{20,52} After 500 hrs, the MPP tracking for the heated device was paused but the cell remained under illumination at 65° C., after 12 hours the MPP tracking was resumed. The PCE of the device recovered to 99% of initial PCE; an encouraging indicator of real-world long-term stability.⁵³ The device structure was not altered for stability testing and the initial efficiency of both devices was >23%. Therefore, the present techniques allow obtaining the first ISOS-L-3 accelerated aging test that directly corresponds to the high efficiency (>20% PCE) PSCs.

All the materials were used as received without purification. Commercial ITO substrates (20 Ω/sq) with 25 mm×25 mm dimension were purchased from TFD Inc. Lead iodide (PbI₂) and bathocuproine (BCP) were purchased from TCI. CsI (99.999%) and C₆₀ (99.5%) were purchased from Sigma-Aldrich. Phenethylammonium iodide (PEAI), Formamidinium iodide (FAI), Methylammonium iodide (MAI) were purchased from GreatCell Solar. 2-fluoro-phenethylammonium iodide (2F-PEAI), 3-fluoro-phenethylammonium iodide (3F-PEAI), 4-fluoro-phenethylammonium iodide (4F-PEAI) and 1-naphthylmethylammonium iodide (NPMAI) were purchased from Xi'an Polymer Light Technology Corp. PCBM was purchased from nano-C. All the solvents used in the process were anhydrous and purchased from Sigma-Aldrich.

The NiOₓ nanoparticles (NCs) were prepared via the hydrolysis reaction of nickel nitrate referring to previous work.^{54,55} Briefly, 20 mmol Ni (NO₃)₂·6H₂O was dissolved in 20 mL of deionized water to obtain a dark green solution. Then, 4 mL of NaOH aqueous solution (10 mol L⁻¹) was slowly added into the solution while stirring. After being stirred for 20 min, the colloidal precipitation was thoroughly washed with deionized water three times and dried at 80° C. for 6 hours. The obtained green powder was then calcined at 270° C. for 2 hours to obtain a dark-black powder. The NiOₓ NCs ink was prepared by dispersing the obtained NiOₓ NCs in mixed solution of deionized water and IPA (3/1, v/v) with a concentration of 10 mg mL⁻¹.

ITO glass was cleaned by sequentially washing with detergent, deionized water, acetone and isopropanol (IPA). Before use, the ITO was cleaned with ultraviolet ozone for 20 min.

For inverted solar cells, the substrate was spin-coated with a thin layer of NiOₓ nanoparticle film from the NiOₓ NCs ink at 2,000 rpm for 30 s. The perovskite absorber layers were deposited inside the N₂-filled glove box with a controlled H₂O and oxygen level to less than 1 ppm. The temperature inside was monitored to be 25-30° C. The precursors for Cs_{0.05}FA_{0.85}MA_{0.1}PbI₃ perovskites were prepared by dissolving the PbI₂, MAI, CsI, and FAI in DMF:DMSO (4:1 in volume) solvents. This was done by adding the powders to a 20 mL vial, then adding 1 mL of mixed solvent and then leaving the vial on a stirring hotplate set to 60° C. for 30 minutes; all steps were undertaken in a glovebox. For the perovskite film fabrication, the substrate was spun at 2000 RPM for 30 s with an acceleration of 1000 rpm at first, and then at 6000 rpm for the 10 s with an acceleration of 6000 rpm/s. In the second step, 150 μL Anisole was dropped onto the substrate during the last 5 s of the spinning. The substrate was immediately placed on a hotplate and annealed at 100° C. for 10 min. For the surface treatment, the 2D solutions were prepared by dissolving the 2D ligand salts (PEAI, BTAI, 3F-PEAI, HAI, OTAI) with or without MAI and DMF in IPA. 1 mg mL⁻¹ of ligand salt, 0.5 mg mL⁻¹ of MAI and an IPA:DMF vol. ratio of 1:200 was used, unless stated otherwise. The 2D layer was fabricated by depositing 150 μL of 2D solution onto the perovskite film surface, immediately after deposition the film was spun at a spin rate of 4,000 RPM for 30 seconds with a 4,000 RPM/s acceleration. The film was then annealed at 100° C. for 5 min.

C₆₀/ALD-SnO₂ or PCBM/BCP were used as the electron transporting layer. C₆₀ was formed by evaporation, and deposition of ALD-SnO₂ was carried out in the PICOSUN R-200 Advanced ALD system. H₂O and TDMASn were used as oxygen and tin precursors. Precursor and substrate temperature was set to 75° C. and 85° C., respectively. 90 SCCM N₂ was used as carrier gas. Pulse and purge times for H₂O were 1s and 5 s, respectively; and 1.6 s and 5 s for TDMASn. The total deposition cycle is 134, corresponding to 20 nm of SnO₂.

PCBM was formed by spin-coating the PCBM solution (20 mg mL⁻¹ in chlorobenzene) at 1,000 rpm for 30 s and then annealed at 100° C. for 5 min. Then a thin and uniform BCP layer was deposited by drop-casting BCP dissolved in IPA in 2 to 3 drops while spinning the substrate at 5000 rpm. Finally, a 120 nm thick Ag contact was deposited on top of BCP using thermal evaporation under high vacuum (<5×10-7 Torr) in an Angstrom Engineering deposition system to produce a 0.053 cm² active area cell.

For non-inverted solar cells, the substrate was spin-coated with a thin layer of SnO₂ nanoparticle solution (1:3:3, SnO₂ (15% in water):IPA:Water) at 3,000 rpm. for 20 s and annealed in ambient air at 150° C. for 1 hour. The perovskite solution was prepared by dissolving 889 mg mL⁻¹ of FAPbI₃, 33 mg mL⁻¹ of MAPbBr₃ and 33 mg mL⁻¹ of MACl in DMF/DMSO (8:1 v/v) mixed solvent. Then, the solution was coated onto the ITO/SnO₂ substrate by two consecutive spin-coating steps, at 1,000 and 2,500 r.p.m. for 5s and 20s, respectively. During the second spin-coating (2,500 r.p.m.) step, 1 mL of diethyl ether was poured onto the substrate after 15 s. The intermediate phase substrate was then put on a hot plate at 150° C. for 10 min. After the fabrication of the 3D perovskite film, the 2D layer was fabricated by depositing a 5 mg mL⁻¹ solution of phenethyl ammonium iodide (PEAI) in isopropanol onto the perovskite film and then spinning the substrate at 4,000 r.p.m. for 30 s. Then, the substrate was heat-treated at 100° C. for 5 minutes. For deposition of the hole-transport material, a spiro-OMeTAD solution in chlorobenzene (CB) (90.9 mg mL⁻¹) was prepared, and 23 μl of lithium-bis(trifluoromethanesulfonyl) imide (Li-TFSI) solution in acetonitrile (ACN) (540 mg mL⁻¹) and 39 μl of pure 4-tert-butylpyridine (tBP) were added in 1.1 mL of the solution. The spiro-OMeTAD solution including additives was spin-coated onto the perovskite surface at 1,750 r.p.m. for 30 s. Finally, a gold electrode was deposited by thermal evaporation to produce a 0.053 cm² active area cell.

Reduced-dimensional (PEA)₂(MA/FA/Cs)ₙ₋₁PbI₃ₙ₊₁ perovskite solutions were prepared by dissolving the appropriate stoichiometric quantities of PbI₂, methylammonium iodide (MAI) [or formamidinium iodide (FAI) or cesium iodide (Cs)] with phenethylammonium iodide (PEAI) iodide in DMF/DMSO (4:1 volume ratio). The resulting solution was filtered with a PTFE syringe filter (0.2 μm) before deposition. Then, the solution was coated onto the glass substrate by two consecutive spin-coating steps, at 1,000 and 2,500 rpm. for 5 s and 20 s, respectively. During the second spin-coating (2,500 rpm.) step, 1 mL of diethyl ether was poured onto the substrate after 15 s. The intermediate phase substrate was then put on a hot plate at 150° C. for 10 min.

The current density-voltage (J-V) characteristics were measured using a Keithley 2400 source meter under illumination from a solar simulator (Newport, Class A) with a light intensity of 100 S5 mW cm⁻² (checked with a calibrated reference solar cell from Newport). J-V curves were measured in a nitrogen atmosphere with a scanning rate of 100 mVs⁻¹ (voltage step of 10 mV and delay time of 200 ms). The active area was determined by the aperture shade mask (0.049 cm² for small-area devices) placed in front of the solar cell. A spectral mismatch factor of 1 was used for all J-V measurements. For stabilised output measurements at maximum power point (MPP), the device testing chamber was left under ambient conditions. Solar cells were fixed at the MPP voltage, (determined from J-V sweeps in both scanning directions) and current output was tracked over time.

Devices were placed in a homemade stability tracking station. Illumination source is a white light LED with intensity calibrated to match 1-sun conditions. For room temperature tests (ISOS-L-11), device chamber was sealed and supplied with continuous N₂ purging. For ISOS-L-3 aging test, device chamber was left open in a room with 50±10% humidity and solar cell was mounted on a metal plate kept at 65° C. by a heating element. A thermal couple attached to the metal plate was used to monitor and provide feedback control to the heating element to ensure temperature consistency. MPP were tracked by a perturb and observe algorithm that updates the MPP point every 10 s. Encapsulation was done by capping device with a glass slide, using UV-adhesive (Lumtec LT-U001) as sealant.

XRD patterns were collected using a Rigaku D/Max-2500 diffractometer equipped with a Cu Kα1 radiation (λ=1.54056 Å).

GIWAXS measurements were conducted at the BL14B1 beamline of the Shanghai Synchrotron Radiation Facility (SSRF) using X-ray with a wavelength of λ=1.24 Å at a grazing incidence angle of 0.3°, and an exposure time of 80 s. The GIXRD patterns were collected by a MarCCD 225 detector with a sample-detector distance of 280 mm and were presented in q coordinates using the equation q=4π sin θ/λ, where θ is half of the diffraction angle. In the present GIXRD data, q has been calibrated by measuring the XRD from a Lanthanum hexaboride reference sample. Images were calibrated using LaB6 and processed via the Nika software package⁵⁶ and the GIXSGUI MATLAB plug-in⁵⁷.

Simulations of perovskite solar cells were conducted in the heterojunction solar cell simulator SCAPS-1 D, version 3.3.07³⁰.

Scanning probe microscopy experiments were carried out in ambient conditions using an Asylum Research Cypher S AFM and low force constant (k=2.8 N m⁻¹), Ti/Ir coated, silicon cantilevers (ASYELEC.01-R2). Contact-mode AFM was used to simultaneously produce surface and current maps applying a fixed bias voltage of about −0.6 V. Measurements were taken under top-illumination from a 3W white LED.

Femtosecond laser pulses of 1,030 nm generated by a Yb:KGW laser at a 5 kHz repetition rate (Pharos (Light Conversion)), passed through an optical parametric amplifier (Orpheus (Light Conversion)) selected for 450 nm light. The latter served as the pump pulse, whereas the probe pulse was generated by focusing the initial 1030 nm pulse into a sapphire crystal, which resulted in a white-light continuum (Helios (Ultrafast)). With a temporal resolution of the system of ˜350 fs, each time step meant delaying the probe pulse with respect to the pump, with time steps that increased exponentially. Every other pump pulse was blocked with a chopper to determine the change in optical density. After going through a grating spectrograph, the pulses were measured by means of a charge-coupled device (CCD) (Helios (Ultrafast)).

Spinning in situ TA was performed using a purpose-built spinner, designed such that incident probe light could pass through the spinning substrate and be directed into the CCD. The pump-probe delay was set to 1 ps. The time resolution of the system was 0.3 s. The measurements were taken in an ambient atmosphere with 35% relative humidity.

The excitation source was an unfocused beam of a 442 nm c.w. diode laser. Photoluminescence was collected using an integrating sphere with a pre-calibrated fibre coupled to a spectrometer (Ocean Optics QE Pro) with an intensity of ˜100 mW cm⁻². PLQY values were calculated by PLQY=P_{S}/P_{Ex}*A, where λ=1−P_{L}/P_{Ex}, P_{S} is the integrated photon count of sample emission upon laser excitation; P_{Ex} is the integrated photon count of the excitation laser when the sample is removed from integrating sphere, and P_{L} is the integrated photon count of excitation laser when sample is mounted in the integrating sphere and hit by the beam.

Space charge limited current (SCLC) measurements were conducted on electron-only (ITO/SnOx/perovskite/PCBM/Ag) devices and hole-only devices (ITO/NiOₓ/Perovskite/PTAA/Au) separately. A Keithly 2400 source meter was used to measure the relevant J-V curves. The trap density (nₜ) was calculated by space-charge-limited current (SCLC) measurement in the hole-only and electron-only devices. The trap-state density nₜ can be calculated by the following relation:

$${n}_{t} = \frac{{V}_{F T L} ε {ε}_{0}}{e {L}^{2}}$$

where e is the elementary charge, L is the perovskite film thickness (˜650 nm), ε₀ is the vacuum permittivity, e is the relative dielectric constant, and V_{TFL} is the onset voltage of trap-filled limit (TFL) region.

TRPL measurements were performed using a Horiba Fluorolog Time Correlated Single Photon Counting (TCSPC) system with photomultiplier tube detectors. A pulsed laser diode (634 nm, 110-140 ps pulse width) was used as excitation sources for steady-state and transient measurements. For transient measurements, a 7200 ns period for unquenched films, and 800 ns period for quenched (0.28 nJ per pulse) was used to capture accurate lifetimes carrier lifetimes.

For combined ultraviolet photoelectron spectroscopy (UPS) and inverse photoelectron spectroscopy (IPES) measurements, an Excitech H Lyman-α photon source (10.2 eV) with an oxygen-filled beam path was used for excitation and coupled with a PHI 5600 ultrahigh vacuum system with a hemispherical electron energy analyzer. A sample bias of −5 V and a pass energy of 5.85 eV were used for UPS acquisition. Inverse photoelectron spectroscopy (IPES) measurements were performed in the Bremsstrahlung isochromat mode with electron kinetic energies below 5 eV and an emission current of 2 μA to minimize sample damage. A Kimball Physics ELG-2 electron gun with a BaO cathode was used to generate the electron beam and the emitted photons were collected with a bandpass photon detector that included an optical bandpass filter (280 nm for 3F-PEA and BTA treated films, and 254 nm for control and PEA treated) and a photomultiplier tube (R585, Hamamatsu Photonics). Samples were held at a −20 V bias during all IPES measurements and the UHV chamber was blacked-out to exclude external light.

The perovskite films sent for combined UPS/IPES were fabricated on ITO/NiOₓ substrates.

The UPS measurements of quasi-2D perovskite films were carried out with the aid of a Thermo Fisher ESCALAB 250XL; −10 V bias was applied for UPS measurements.

The transient photovoltage/photocurrent measurements were carried out according to an existing technique⁴⁷.

KPFM was conducted on an MFP-3D AFM (Asylum Research, Oxford Instrument) using conductive Ti/Ir coated tips (ASYELEC.01-R2, f=71.72 kHz, k=2.8 N/m). The tips were calibrated using the Sader's method (Rev. Sci. Instrum. 83, 103705, 2012; Rev. Sci. Instrum. 85, 113702, 2014). The KPFM measurement was implemented using a two-path method at a scan rate of 0.5 Hz, where the first pass in every scan line was used to determine the topography and the following second pass was used to measure the contact potential difference between the tip and the sample. The second pass scanned by raising the tip at a fixed 20 nm above the sample following the topography. Each set of samples were arranged in proximity on a common substrate and were measured using the same tip and scanning parameters. Different scanning sequence of the samples was adopted in each set to ensure the obtained potential trend is reliable and the global drift (if any) is not dominating. The two sets of samples (PEA treated and 3F-PEA treated) were measured using different probes, thus a shift in overall potential is observed.

As presented above, the energy landscape of RDPs can be tailored by adjusting their layer width n. While previous work demonstrated that 2D/3D heterostructures containing n=1 and 2 RDPs can be used in PSCs with >25% PCE, prior art methods do not translate to inverted PSCs due to electron blocking at the 2D/3D interface. The techniques described herein result in an increase of the layer width of RDPs in 2D/3D heterostructures in order to address this problem. Bulkier organics form 2D heterostructures more slowly, resulting in wider RDPs. Small modifications to ligand design induce preferential growth of n≥3 RDPs. Levering these insights, efficient inverted PSCs (certified 23.91% quasi-steady state efficiency) can be produced. The unencapsulated devices operate at room temperature and ˜50% relative humidity for over 1000 hrs without loss of PCE and, when subjected to ISOS-L3 accelerated aging encapsulated devices retain 92% of PCE after 500 hrs.

Several alternative embodiments and examples have been described and illustrated herein. The embodiments described above are intended to be exemplary only. A person skilled in the art would appreciate the features of the individual embodiments, and the possible combinations and variations of the components. A person skilled in the art would further appreciate that any of the embodiments could be provided in any combination with the other embodiments disclosed herein. The present examples and embodiments, therefore, are to be considered in all respects as illustrative and not restrictive. Accordingly, while specific embodiments have been illustrated and described, numerous modifications come to mind without significantly departing from the scope defined in the present description and the appended claims.

### REFERENCES AND NOTES

1. Yuan, M. et al. Perovskite energy funnels for efficient light-emitting diodes. Nat. Nanotechnol. 11, 872-877 (2016).
2. Wei, M. et al. Ultrafast narrowband exciton routing within layered perovskite nanoplatelets enables low-loss luminescent solar concentrators. Nat. Energy 4, 197-205 (2019).
3. Proppe, A. H. et al. Synthetic Control over Quantum Well Width Distribution and Carrier Migration in Low-Dimensional Perovskite Photovoltaics. J. Am. Chem. Soc. 140, 2890-2896 (2018).
4. Quan, L. N. et al. Ligand-Stabilized Reduced-Dimensionality Perovskites. J. Am. Chem. Soc. 138, 2649-2655 (2016).
5. Jung, E. H. et al. Efficient, stable and scalable perovskite solar cells using poly(3-hexylthiophene). Nature 567, 511-515 (2019).
6. Min, H. et al. Efficient, stable solar cells by using inherent bandgap of a-phase formamidinium lead iodide. Science (80-.). 366, 749-753 (2019).
7. Jeong, M. et al. Stable perovskite solar cells with efficiency exceeding 24.8% and 0.3-V voltage loss. Science (80-.). 369, 1615-1620 (2020).
8. Jiang, Q. et al. Surface passivation of perovskite film for efficient solar cells. Nat. Photonics 13, 460-466 (2019).
9. Zhu, H. et al. Tailored Amphiphilic Molecular Mitigators for Stable Perovskite Solar Cells with 23.5% Efficiency. Adv. Mater. 32, 1907757 (2020).
10. Liu, Y. et al. Ultrahydrophobic 3D/2D fluoroarene bilayer-based water-resistant perovskite solar cells with efficiencies exceeding 22%. Sci. Adv. 5, eaaw2543 (2019).
11. Kim, G. et al. Impact of strain relaxation on performance of a-formamidinium lead iodide perovskite solar cells. Science (80-.). 370, 108-112 (2020).
12. Jeong, J. et al. Pseudo-halide anion engineering for α-FAPbI3 perovskite solar cells. Nature 592, 381 (2021).
13. Teale, S. et al. Dimensional Mixing Increases the Efficiency of 2D/3D Perovskite Solar Cells. J. Phys. Chem. Lett. 5115-5119 (2020) doi:10.1021/acs.jpclett.Oc01444.
14. Yoo, J. J. et al. An interface stabilized perovskite solar cell with high stabilized efficiency and low voltage loss. Energy Environ. Sci. 12, 2192-2199 (2019).
15. Hu, Y. et al. Hybrid Perovskite/Perovskite Heterojunction Solar Cells. ACS Nano 10, 5999-6007 (2016).
16. Proppe, A. H. et al. Multication perovskite 2D/3D interfaces form via progressive dimensional reduction. Nat. Commun. 12, 3472 (2021).
17. Jang, Y. W. et al. Intact 2D/3D halide junction perovskite solar cells via solid-phase in-plane growth. Nat. Energy 6, 63-71 (2021).
18. Zhang, T. et al. Stable and Efficient 3D-2D Perovskite-Perovskite Planar Heterojunction Solar Cell without Organic Hole Transport Layer. Joule 2, 2706-2721 (2018).
19. Bai, S. et al. Planar perovskite solar cells with long-term stability using ionic liquid additives. Nature 571, 245-250 (2019).
20. Lin, Y. H. et al. A piperidinium salt stabilizes efficient metal-halide perovskite solar cells. Science (80-.). 369, 96-102 (2020).
21. Zheng, X. et al. Managing grains and interfaces via ligand anchoring enables 22.3%-efficiency inverted perovskite solar cells. Nat. Energy 5, 131-140 (2020).
22. Chen, S., Xiao, X., Gu, H. & Huang, J. Iodine reduction for reproducible and high-performance perovskite solar cells and modules. Sci. Adv. 7, eabe8130 (2021).
23. Chen, C. et al. Arylammonium-Assisted Reduction of the Open-Circuit Voltage Deficit in Wide-Bandgap Perovskite Solar Cells: The Role of Suppressed Ion Migration. ACS Energy Lett. 5, 2560-2568 (2020).
24. Bai, Y. et al. Dimensional Engineering of a Graded 3D-2D Halide Perovskite Interface Enables Ultrahigh Voc Enhanced Stability in the p-i-n Photovoltaics. Adv. Energy Mater. 7, (2017).
25. Park, S. M., Abtahi, A., Boehm, A. M. & Graham, K. R. Surface Ligands for Methylammonium Lead Iodide Films: Surface Coverage, Energetics, and Photovoltaic Performance. ACS Energy Lett. 5, 799-806 (2020).
26. La-Placa, M. G. et al. Vacuum-Deposited 2D/3D Perovskite Heterojunctions. ACS Energy Lett. 4, 2893-2901 (2019).
27. Zhao, T., Chueh, C. C., Chen, Q., Rajagopal, A. & Jen, A. K. Y. Defect Passivation of Organic-Inorganic Hybrid Perovskites by Diammonium Iodide toward High-Performance Photovoltaic Devices. ACS Energy Lett. 1, 757-763 (2016).
28. Proppe, A. H. et al. Photochemically Cross-Linked Quantum Well Ligands for 2D/3D Perovskite Photovoltaics with Improved Photovoltage and Stability. J. Am. Chem. Soc. 141, 14180-14189 (2019).
29. Mahmud, M. A. et al. Double-Sided Surface Passivation of 3D Perovskite Film for High-Efficiency Mixed-Dimensional Perovskite Solar Cells. Adv. Funct. Mater. 30, 1907962 (2020).
30. Burgelman, M., Nollet, P. & Degrave, S. Modelling polycrystalline semiconductor solar cells. Thin Solid Films vol. 361 527-532 (Elsevier Sequoia SA, 2000).
31. Zhou, L. et al. Highly Efficient and Stable Planar Perovskite Solar Cells with Modulated Diffusion Passivation Toward High Power Conversion Efficiency and Ultrahigh Fill Factor. Sol. RRL 3, 1900293 (2019).
32. Cao, D. H., Stoumpos, C. C., Farha, O. K., Hupp, J. T. & Kanatzidis, M. G. 2D Homologous Perovskites as Light-Absorbing Materials for Solar Cell Applications. J. Am. Chem. Soc. 137, 7843-7850 (2015).
33. Ma, J. & Wang, L. W. Nanoscale charge localization induced by random orientations of organic molecules in hybrid perovskite CH3NH3PbI3. Nano Lett. 15, 248-253 (2015).
34. Quintero-Bermudez, R. et al. Compositional and orientational control in metal halide perovskites of reduced dimensionality. Nat. Mater. 17, 900-907 (2018).
35. Hu, J. et al. Synthetic control over orientational degeneracy of spacer cations enhances solar cell efficiency in two-dimensional perovskites. Nat. Commun. 10, 1-11 (2019).
36. Niu, T. et al. Interfacial Engineering at the 2D/3D Heterojunction for High-Performance Perovskite Solar Cells. Nano Lett. 19, 7181-7190 (2019).
37. Gharibzadeh, S. et al. Record Open-Circuit Voltage Wide-Bandgap Perovskite Solar Cells Utilizing 2D/3D Perovskite Heterostructure. Adv. Energy Mater. 9, 1803699 (2019).
38. Briggs, D. & Seah, M. P. Practical Surface Analysis SECOND EDITION Volume 1 Auger and X-ray Photoelectron Spectroscopy Edited by.
39. Boehm, A. M., Liu, T., Park, S. M., Abtahi, A. & Graham, K. R. Influence of Surface Ligands on Energetics at FASnI3/C60 Interfaces and Their Impact on Photovoltaic Performance. ACS Appl. Mater. Interfaces 12, 5209-5218 (2020).
40. Yoshida, H. Near-ultraviolet inverse photoemission spectroscopy using ultra-low energy electrons. Chem. Phys. Lett. 539-540, 180-185 (2012).
41. Boehm, A. M., Wieser, J., Butrouna, K. & Graham, K. R. A new photon source for ultraviolet photoelectron spectroscopy of organic and other damage-prone materials. Org. Electron. 41, 9-16 (2017).
42. Endres, J. et al. Valence and Conduction Band Densities of States of Metal Halide Perovskites: A Combined Experimental-Theoretical Study. J. Phys. Chem. Lett. 7, 2722-2729 (2016).
43. She, X. J. et al. A solvent-based surface cleaning and passivation technique for suppressing ionic defects in high-mobility perovskite field-effect transistors. Nat. Electron. 3, 694-703 (2020).
44. Kirchartz, T., Márquez, J. A., Stolterfoht, M. & Unold, T. Photoluminescence-Based Characterization of Halide Perovskites for Photovoltaics. Adv. Energy Mater. 10, 1904134 (2020).
45. Zhou, M., Sarmiento, J. S., Fei, C. & Wang, H. Charge Transfer and Diffusion at the Perovskite/PCBM Interface Probed by Transient Absorption and Reflection. J. Phys. Chem. C 123, 22095-22103 (2019).
46. Proppe, A. H. et al. Spectrally Resolved Ultrafast Exciton Transfer in Mixed Perovskite Quantum Wells. J. Phys. Chem. Lett. 10, 419-426 (2019).
47. Shao, Y., Yuan, Y. & Huang, J. Correlation of energy disorder and open-circuit voltage in hybrid perovskite solar cells. Nat. Energy 1, 1-6 (2016).
48. Chen, W. et al. Efficient and stable large-area perovskite solar cells with inorganic charge extraction layers. Science (80-.). 350, 944-948 (2015).
49. Ma, F. et al. Nickel oxide for inverted structure perovskite solar cells. Journal of Energy Chemistry vol. 52 393-411 (2020).
50. Boyd, C. C. et al. Overcoming Redox Reactions at Perovskite-Nickel Oxide Interfaces to Boost Voltages in Perovskite Solar Cells. Joule 4, 1759-1775 (2020).
51. Sutanto, A. A. et al. Dynamical evolution of the 2D/3D interface: A hidden driver behind perovskite solar cell instability. J. Mater. Chem. A 8, 2343-2348 (2020).
52. Khenkin, M. V. et al. Consensus statement for stability assessment and reporting for perovskite photovoltaics based on ISOS procedures. Nat. Energy 5, 35-49 (2020).
53. Lu, H. et al. Vapor-assisted deposition of highly efficient, stable black-phase FAPbI3 perovskite solar cells. Science (80-.). 370, (2020).
54. Chen, H. et al. Efficient and Stable Inverted Perovskite Solar Cells Incorporating Secondary Amines. Adv. Mater. 31, 1903559 (2019).
55. Chen, H. et al. Band alignment towards high-efficiency NiOx-based Sn—Pb mixed perovskite solar cells. Sci. China Mater. 44, 215 (2020).
56. Ilavsky, J. Nika: Software for two-dimensional data reduction. J. Appl. Crystallogr. 45, 324-328 (2012).
57. Jiang, Z. GIXSGUI: A MATLAB toolbox for grazing-incidence X-ray scattering data visualization and reduction, and indexing of buried three-dimensional periodic nanostructured films. J. Appl. Crystallogr. 48, 917-926 (2015).

1. A photovoltaic device, comprising:
a substrate;
a hole-transport layer coating at least a portion of the substrate;
a light-harvesting heterostructure coating at least a portion of the hole-transport layer, the light-harvesting heterostructure comprising:
a 3D perovskite material; and
a 2D perovskite capping material extending over at least a portion of the 3D perovskite material, the 2D perovskite capping material comprising:
one or more perovskite layers, each perovskite layer having a corresponding width n, wherein a majority of the corresponding width n is greater or equal to 3; and
a spacer extending between two subsequent perovskite layers;
an electron-transport layer coating at least a portion of the light-harvesting heterostructure; and
a pair of electrodes operatively connected to the substrate, the hole-transporting layer, the light-harvesting heterostructure and the electron-transport layer.

2. The photovoltaic device of claim 1, wherein the 3D perovskite material is Cs_{0.05}MA_{0.1} FA_{0.85}PbI₃.

3. The photovoltaic device of claim 1, wherein the perovskite layers each comprise a compound of general formula (FA)ₙ₋₁PbnI₃ₙ₋₁.

4. The photovoltaic device of claim 1, wherein the spacer is an organic ligand selected from the group consisting of: phenethylammonium, 4-fluoro-phenethylammonium, 3-fluoro-phenethylammonium, 2-fluoro-phenethylammonium, butylammonium, hexylammonium, octylammonium, and 1-naphthylmethylammonium.

5. The photovoltaic device of claim 1, wherein the hole-transport layer comprises NiOₓ.

6. The photovoltaic device of claim 1, wherein the electron-transport layer comprises C₆₀/ALD-SnO₂ or PCBM/BCP.

7. A method for manufacturing a photovoltaic device, the method comprising:
coating at least a portion of a substrate with a hole-transport layer;
forming a light-harvesting heterostructure on the hole-transport layer, said forming the light-harvesting heterostructure comprising:
coating the hole-transport layer with a 3D perovskite material;
treating a surface of the 3D perovskite material with a 2D perovskite solution to form a 2D perovskite capping material extending over at least a portion of the 3D perovskite material, the 2D perovskite capping material comprising:
one or more perovskite layers, each perovskite layer having a corresponding width n, wherein a majority of the corresponding width n is greater or equal to 3; and
a spacer extending between two subsequent perovskite layers; and
coating at least a portion of the light-harvesting heterostructure with an electron-transport layer.

8. The method of claim 7, further comprising preparing the 3D perovskite material, said preparing the 3D perovskite material comprising dissolving PbI₂, MAI, CsI, and FAI in DMF:DMSO solvents to obtain a 3D perovskite solution.

9. The method of claim 8, further comprising spin coating the 3D perovskite solution on the hole-transport layer.

10. The method of claim 7, further comprising preparing the 2D perovskite solution, said preparing the 2D perovskite material comprising dissolving 2D ligand salts with MAI in DMF:IPA solvents.

11. The method of claim 10, further comprising spin coating the 2D perovskite solution on the 3D perovskite material.

12. A photovoltaic device, comprising:
a substrate;
an electron-transport layer coating at least a portion of the substrate;
a light-harvesting heterostructure coating at least a portion of the electron-transport layer, the light-harvesting heterostructure comprising:
a 3D perovskite material; and
a 2D perovskite capping material extending over at least a portion of the 3D perovskite material, the 2D perovskite capping material comprising:
one or more perovskite layers, each perovskite layer having a corresponding width n, wherein a majority of the corresponding width n is greater or equal to 3; and
a spacer extending between two subsequent perovskite layers;
a hole-transport coating at least a portion of the light-harvesting heterostructure; and
a pair of electrodes operatively connected to the substrate, the electron-transport layer, the light-harvesting heterostructure and the hole-transporting layer.

13. The photovoltaic device of claim 12, wherein the perovskite layers each comprise a compound of general formula (FA)ₙ₋₁PbnI₃ₙ₋₁.

14. The photovoltaic device of claim 12, wherein the spacer is an organic ligand selected from the group consisting of: phenethylammonium, 4-fluoro-phenethylammonium, 3-fluoro-phenethylammonium, 2-fluoro-phenethylammonium, butylammonium, hexylammonium, octylammonium, and 1-naphthylmethylammonium.

15. The photovoltaic device of claim 12, wherein the electron-transport layer comprises SnO₂.

16. The photovoltaic device of claim 12, wherein the hole-transport layer comprises Spiro-OMeTAD.

17. A method for manufacturing a photovoltaic device, the method comprising:
coating at least a portion of a substrate with an electron-transport layer;
forming a light-harvesting heterostructure on the electron-transport layer, said forming the light-harvesting heterostructure comprising:
coating the electron-transport layer with a 3D perovskite material;
treating a surface of the 3D perovskite material with a 2D perovskite solution to form a 2D perovskite capping material extending over at least a portion of the 3D perovskite material, the 2D perovskite capping material comprising:
one or more perovskite layers, each perovskite layer having a corresponding width n, wherein a majority of the corresponding width n is greater or equal to 3; and
a spacer extending between two subsequent perovskite layers; and
coating at least a portion of the light-harvesting heterostructure with a hole-transport layer.

18. The method of claim 17, further comprising preparing the 3D perovskite material, said preparing the 3D perovskite material comprising dissolving FAPbI3, MAPbBr₃ and MACl in a DMF:DMSO solvent to obtain a 3D perovskite solution.

19. The method of claim 17, further comprising preparing the 2D perovskite solution, said preparing the 2D perovskite material comprising dissolving phenethyl ammonium iodide in isopropanol.

20. A light-harvesting heterostructure for a photovoltaic device, the photovoltaic device comprising at least an electron-transport layer and a hole-transport layer, the light-harvesting heterostructure comprising:
a 3D perovskite material contacting one of the electron-transport layer and the hole-transport layer; and
a 2D perovskite capping material extending over at least a portion of the 3D perovskite material and contacting another one of the electron-transport layer and the hole-transport layer, the 2D perovskite capping material comprising:
one or more perovskite layers, each perovskite layer having a corresponding width n, wherein a majority of the corresponding width n is greater or equal to 3; and
a spacer extending between two subsequent perovskite layers.
